(19) United States
(12) Patent Application Publication
(10) Pub. No.: US 2009/0268384 A1
(43) Pub. Date: Oct. 29, 2009

(54) HOUSING, ELECTRONIC DEVICE USING THE HOUSING, AND MANUFACTURING METHOD THEREOF

(75) Inventors: CHE-YUAN HSU, Shindian (TW); FU-KENG YANG, Shindian (TW); CHENG-WEN SU, Shindian (TW); YI-QIANG XU, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: SHENZHEN FUTAIHONG PRECISION INDUSTRY CO., LTD., ShenZhen City (CN); FIH (HONG KONG) LIMITED, Kowloon (HK)

(21) Appl. No.: 12/420,916

(22) Filed: Apr. 9, 2009

(30) Foreign Application Priority Data
Apr. 28, 2008 (CN) 2008-10301357.8

(51) Int. Cl. H05K 5/00; B44C 1/22

(52) U.S. Cl. 361/679.01; 216/33

(57) ABSTRACT

A housing for an electronic device comprises a thin film defining concave portions thereon; a decorative pattern having a mirror-effect formed in the concave portions; and a substrate attached to the decorative pattern and the thin film. A method for manufacturing the housing and an electronic device using the housing are also disclosed.

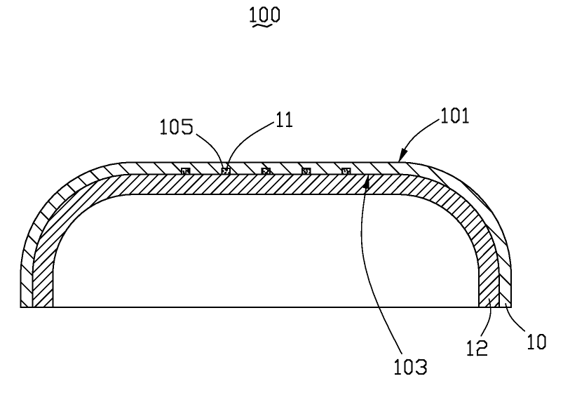

### BACKGROUND

1. Technical Field

The present disclosure generally relates to housings, and particularly, to a housing for an electronic device, and a method for making the housing.

2. Description of Related Art

Portable electronic devices such as mobile phones, laptops and personal digital assistants (PDAs) are widely used. Most housings of portable electronic devices are made by in mold labelling (IML). A typical housing includes a transparent plastic film, a pattern attached to the transparent plastic film, and a substrate moldingly attached to the transparent plastic film by an injection molding process. To achieve a mirror-effect, an ink coating including silver ions is printed on the transparent plastic film to form a pattern. Then, the substrate is attached to the pattern. However, the silver ions of the ink coating are prone to oxidation at the high temperatures reached during injection molding the substrate. Furthermore, the ink coating is prone to deformation at high temperatures, thereby reducing production efficiency.

Therefore, there is room for improvement within the art.

### BRIEF DESCRIPTION OF THE FIGURE

Many aspects of the housing for an electronic device can be better understood with reference to the FIGURE. The components in the FIGURE are not necessarily drawn to scale, the emphasis instead being placed upon clearly illustrating the principles of the housing for an electronic device.

The FIGURE is a cross sectional view of an exemplary housing.

### DETAILED DESCRIPTION OF THE DISCLOSURE

Referring to the FIGURE, an exemplary housing 100 includes a thin film 10, a decorative pattern 11 attached to the thin film 10, and a substrate 12 moldingly attached to the decorative pattern 11 and the thin film 10 if the decorative pattern 11 does not completely covers the thin film 10.

The thin film 10 is made of plastic material selected from a group consisting of polycarbonate (PC), polyethylene terephthalate (PET), polymethylmethacrylate (PMMA), or polylactic acid (PLA). The thin film 10 includes an outer surface 101 and an opposite inner surface 103. The inner surface 103 defines a plurality of concave portions 105 made by laser etching.

The decorative pattern 11 is made of a shiny ink having a mirror-effect formed in the concave portions 105. The ink includes metal ions, such as silver ions, etc.

The substrate 12 is made of plastic and moldingly attached to the decorative pattern 11 and the thin film 10 by an injection molding process. The substrate 12 can be made of polycarbonate (PC), polyethylene terephthalate (PET), acrylonitrile-butadiene-styrene (ABS), polymethylmethacrylate (PMMA), polyethylene (PE) or polyamide (PA).

During a process for manufacturing the housing 100, the thin film 10 is provided.

A laser beam emitter is provided for etching the inner surface 103 of the thin film 10 to form a plurality of concave portions 105. The concave portions 105 receive ink to form patterns.

The ink is filled into the concave portions 105 and at the same level as the inner surface 103 of the thin film 10. The ink includes metal ions, such as silver ions, etc, which gives the ink a shiny, mirror-like appearance.

The ink is then heated and dried.

An injection mold is provided. The thin film 10 with the ink is placed into the injection mold. A substrate 12 is moldingly attached to the thin film 10 and the ink by injection molding.

The ink is received in the concave portions 105 to form the patterns, therefore, deformation of the ink can be avoided during the injection molding. Furthermore, the ink has a thickness when it is received in the concave portions 105. A top portion of the ink is at the same level as the inner surface 103 of the thin film 10. Only the top portion of the ink is oxidized during injection molding the substrate 10. The other portion of the ink is not oxidized at high temperature, therefore the method of manufacturing the housing 100 improves production efficiency.

It should be understood, the housing 100 may be used in mobile phones, cameras, spectacle cases or boxes, etc.

It should be also understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A housing for an electronic device, comprising:
a thin film defining concave portions;
a decorative pattern having a mirror-effect formed in the concave portions; and
a substrate attached to the decorative pattern and the thin film.

2. The housing as claimed in claim 1, wherein the concave portions are defined in the thin film by laser etching.

3. The housing as claimed in claim 1, wherein the decorative pattern is made of ink including silver ions.

4. The housing as claimed in claim 1, wherein the substrate is made of plastic and attached to the decorative pattern and the thin film by an injection molding process.

5. The housing as claimed in claim 1, wherein the substrate is selected from a group consisting of polycarbonate, polyethylene terephthalate, acrylonitrile-butadiene-styrene, polymethylmethacrylate, polyethylene or polyamide.

6. An electronic device, comprising:
a housing, comprising:
a thin film defining concave portions;
a decorative pattern having a mirror-effect formed in the concave portions; and
a substrate attached to the decorative pattern and the thin film.

7. The electronic device as claimed in claim 6, wherein the concave portions are formed in the thin film by laser etching.

8. The electronic device as claimed in claim 6, wherein the decorative pattern is made of ink including silver ions.

9. The electronic device as claimed in claim 6, wherein the substrate is made of plastic and attached to the decorative pattern and the thin film by an injection molding process.

10. The electronic device as claimed in claim 6, wherein the substrate is made of polycarbonate, polyethylene terephthalate, acrylonitrile-butadiene-styrene, polymethylmethacrylate, polyethylene or polyamide.

11. A method for manufacturing a housing for an electronic device, comprising:
providing a thin film;
etching concave portions in the thin film;
filling ink having a mirror-effect into the concave portions of the thin film; and
attaching a substrate to the thin film and the ink.

12. The method as claimed in claim 11, wherein the thin film is made of polycarbonate, polyethylene terephthalate, polymethylmethacrylate, or polylactic acid.

13. The method as claimed in claim 11, wherein the concave portions are formed in an inner surface of the thin film by laser etching.

14. The method as claimed in claim 11, wherein the ink includes silver ions.

15. The method as claimed in claim 11, wherein the substrate is selected from a group consisting of polycarbonate, polyethylene terephthalate, acrylonitrile-butadiene-styrene, polymethylmethacrylate, polyethylene or polyamide.
